(19) United States
(12) Patent Application Publication
(10) Pub. No.: US 2009/0057266 A1
(43) Pub. Date: Mar. 5, 2009

(54) LINE EDGE ROUGHNESS CONTROL

(76) Inventors: Eda Tuncel, Menlo Park, CA (US); George Kovall, Campbell, CA (US)

Correspondence Address: MACPHERSON KWOK CHEN & HEID LLP, 2033 GATEWAY PLACE, SUITE 400, SAN JOSE, CA, 95110, US

(21) Appl. No.: 11/845,613

(22) Filed: Aug. 27, 2007

(51) Int. Cl. H01L 21/302

(52) U.S. Cl. 216/41

(57) ABSTRACT

In one embodiment, a method includes providing a plasma etch reactor including a vacuum chamber and an electrode disposed inside of the chamber, and providing a stack to be etched over the electrode, the stack including a patterned photoresist over a dielectric layer. The method further includes providing a chamber pressure between about 75 mT and about 150 mT, flowing gases including CF₄ and CHF₃ at a ratio between about 2.5:1 and about 5.0:1 into the chamber, applying RF power to the electrode between about 300 W and about 500 W to form a plasma from the gases, and etching the dielectric layer with the plasma through the patterned photoresist.

### BACKGROUND

1. Field of Disclosure

The present disclosure relates generally to the manufacture of semiconductor devices, and more particularly to etching of a dielectric with improved line edge roughness and line width roughness control.

2. Description of Related Art

Due to imperfections in the patterning process of semiconductor devices, printed lines and gates exhibit a certain roughness along etched surfaces. One measurement of the roughness imperfection is line edge roughness (LER) and another measurement is line width roughness (LWR). These rough surfaces can degrade the electrical performance of transistors and die yield, becoming more prominent as transistors and devices decrease in size and scale.

Prior methods for reducing LER or LWR have focused on photolithography. In one example, pre-curing of ArF photoresists have been effective at reducing LER but has increased integration complexity. Thus, an improved method for reducing LER and LWR that is efficient and does not increase integration complexity is desirable.

### SUMMARY

The present invention provides an advantageous plasma etch method for controlling and reducing LER and LWR on etched surfaces.

In accordance with one embodiment of the present invention, a method includes providing a plasma etch reactor including a vacuum chamber and an electrode disposed inside of the chamber, and providing a stack to be etched over the electrode, the stack including a patterned photoresist over a dielectric layer. The method further includes providing a chamber pressure between about 75 mT and about 150 mT, flowing gases including CF₄ and CHF₃ at a ratio between about 2.5:1 and about 5.0:1 into the chamber, applying RF power to the electrode between about 300 W and about 500 W to form a plasma from the gases, and etching the dielectric layer with the plasma through the patterned photoresist.

In accordance with another embodiment of the present invention, another method includes providing a substrate, providing a polysilicon layer over the substrate, providing an oxide layer over the polysilicon layer, providing a SiON layer over the oxide layer, providing an ARC layer over the SiON layer, and providing a patterned photoresist over the ARC layer. The method further includes etching the oxide layer through the photoresist, the ARC layer, and the SiON layer with a plasma formed with a gas mixture including CH₄ and CHF₃ at a ratio between about 2.5:1 and about 5.0:1, at a pressure between about 75 mT to about 150 mT, and at a bias power level between about 300 W and about 500 W. The polysilicon layer may then be etched through the etched oxide layer to form a gate.

Advantageously, the present invention provides for plasma etch methods to reduce and control LER and LWR, thereby maintaining a small variation from the line width nominal value in an efficient manner. The present disclosure also provides for tight wafer center-to-edge line width, LER and LWR uniformity.

The scope of the invention is defined by the claims, which are incorporated into this section by reference. A more complete understanding of embodiments of the present invention will be afforded to those skilled in the art, as well as a realization of additional advantages thereof, by a consideration of the following detailed description of one or more embodiments. Reference will be made to the appended sheets of drawings that will first be described briefly.

### BRIEF DESCRIPTION OF THE DRAWINGS

FIG. 1A is a schematic cross-sectional view of an example of a stack to be etched in accordance with an embodiment of the present invention.

FIG. 1B is a schematic cross-sectional view of the stack in FIG. 1A after an etch with reduced LER and LWR in accordance with an embodiment of the present invention.

FIG. 2 is a schematic illustration of an example of a plasma etch reactor.

FIG. 3 illustrates a flowchart of a method for reducing LER and LWR in accordance with an embodiment of the present invention.

Embodiments of the present invention and their advantages are best understood by referring to the detailed description that follows. It should be appreciated that like reference numerals are used to identify like elements illustrated in one or more of the figures. It should also be appreciated that the figures may not be necessarily drawn to scale.

### DETAILED DESCRIPTION

The present invention provides an advantageous plasma etch method for controlling and reducing line etch roughness (LER) and line width roughness (LWR). In a particular example, LER and LWR are reduced in the etching of an oxide hard mask that may subsequently be used for the patterning of array gate structures. In a further example, a post oxide hard mask etch morphology for 0.22/0.16 micron lines/spaces defined with a 193 nm lithography photoresist is improved.

In one example, LER may be defined as the 3 σ of the horizontal distances of an edge location from a fitted line, and LWR may be defined as the 3 σ of the line width, as provided in “VeritySEM™ 3D User Manual, Part Number: 30861001000” from Applied Materials, Inc. of Santa Clara, Calif. Definitions and models for LER and LWR may also be found in “Line Edge Roughness: Characterization, Modeling and Impact on Device Behavior”, J. A. Croon et al., IEDM, pp. 307-310 (2002), the contents of which are incorporated by reference herein.

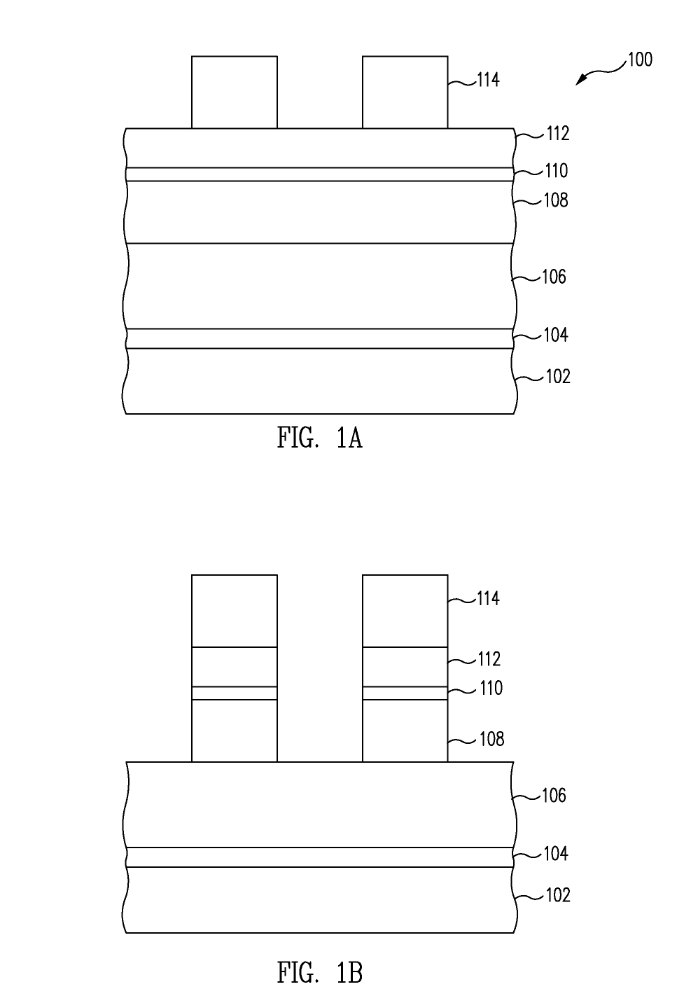

FIG. 1A is a schematic cross-sectional view of an example of a stack 100 to be etched in accordance with an embodiment of the present invention. Stack 100 includes a substrate 102, an oxide layer 104 over substrate 102, a polysilicon layer 106 over oxide layer 104, a dielectric layer 108 over polysilicon layer 106, a SiON layer 110 over dielectric layer 108, and an organic anti-reflective coating (ARC) layer 112 over SiON layer 110. The layers may be provided over the substrate by chemical vapor deposition (CVD), spin-on coating, and/or by other various means and methods. On top of the stack is a patterned photoresist layer 114 to be used for advantageously defining dielectric layer 108 with reduced LER and LWR. In one embodiment, photoresist 114 has a thickness of about 2,800 angstroms, ARC layer 112 has a thickness of about 1,120 angstroms, SiON layer 110 has a thickness of about 350 angstroms, and dielectric layer 108 has a thickness of about 2,100 angstroms. It is noted that the invention is not limited to the aforementioned example but can involve various layers and layer thicknesses depending upon desired applications of the present disclosure.

Substrate 102 may be a wafer formed from a single crystalline silicon material, but may also comprise other materials, for example, an epitaxial material, a polycrystalline semiconductor material, or other suitable material. Substrate 102 may be doped by conventional means with dopants at different dosage and energy levels. It is noted that substrate 102 can further include additional layers, structures, and/or devices.

In one example, the dielectric layer may include an oxide or a nitride, and in another example, includes a plasma enhanced SiH₄ oxide. The photoresist is sensitive at 193 nm in one example but is not limited thereto. Those skilled in the art of depositing organic ARC material will understand that different ARC formulations may be used and that the selected ARC fluid may be adapted for providing either a substantially planar top surface or a nonplanar top surface. Commercially-available ARC precursor fluid formulations are applicable.

FIG. 1B is a schematic cross-sectional view of the stack in FIG. 1A after an etch of the dielectric layer through the photoresist, ARC layer, and SiON layer, with reduced LER and LWR in accordance with an embodiment of the present invention. Etched dielectric layer 108 may subsequently be used as a hardmask for etching polysilicon layer 106 to form a gate.

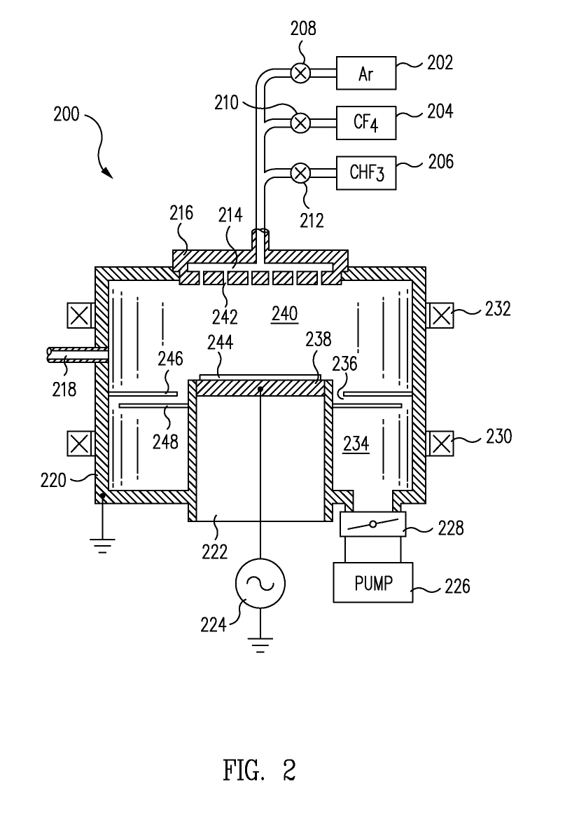

FIG. 2 is a schematic illustration of an example of a plasma etch reactor 200 that may be used to execute the methods of the present disclosure. This illustration is based on the Super-e etch reactors available from Applied Materials, Inc. of Santa Clara, Calif. Reactor 200 includes a grounded vacuum chamber 220, optionally including liners to protect the walls. A wafer 244 is inserted into the chamber 220 through a slit valve opening 218 and placed on a cathode pedestal 222 with an electrostatic chuck 238 selectively clamping the wafer. The chuck powering is not illustrated. Unillustrated fluid cooling channels through the pedestal 222 maintain the pedestal at reduced temperatures. In one example, a thermal transfer gas such as helium is supplied to unillustrated grooves in the upper surface of the pedestal 222. The thermal transfer gas increases the efficiency of thermal coupling between the pedestal 222 and the wafer 244, which is held against the pedestal 222 by the electrostatic chuck 238 or an alternatively used peripheral wafer clamp.

An RF power supply 224, preferably operating at 13.56 MHz, is connected to the cathode pedestal 222 and provides power for generating the plasma while also controlling the DC self-bias. Magnetic coils 230, 232 powered by unillustrated current supplies surround the chamber 220 and generate a slowly rotating (on the order of seconds and typically less than 10 ms), horizontal, essentially DC magnetic field in order to increase the density of the plasma. A vacuum pump system 226 pumps the chamber 220 through an adjustable throttle valve 228. Shields 246, 248 not only protect the chamber 220 and pedestal 222 but also define a baffle 236 and a pumping channel 234 connected to the throttle valve 228.

Processing gases are supplied from gas sources 202, 204, 206 through respective mass flow controllers 208, 210, 212 to a quartz gas distribution plate 216 positioned in the roof of the chamber 220 overlying the wafer 244 and separated from it across a processing region 240. The composition of the etching gas is a subject matter of one aspect of the present invention. The distribution plate 216 includes a manifold 214 receiving the processing gas and communicating with the processing region 240 through a showerhead having a large number of distributed apertures 242 so as to inject a more uniform flow of processing gas into the processing region 240.

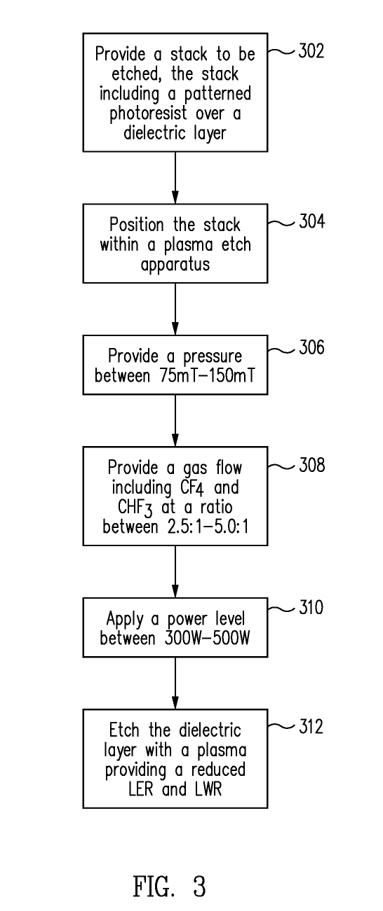

FIG. 3 illustrates a flowchart of a method for reducing LER and LWR in accordance with an embodiment of the present invention.

At step 302, a stack to be etched is provided, the stack including a patterned photoresist over a dielectric layer (e.g., photoresist 114 over dielectric layer 108 of FIG. 1A).

At step 304, the stack is operably positioned inside a plasma etch apparatus (e.g., wafer 244 within plasma etch reactor 200 of FIG. 2).

At step 306, a chamber pressure is provided between about 75 mT and about 150 mT (e.g., using pump 226 of FIG. 2). Increasing process chamber pressure has been determined to decrease LER, LWR, and within wafer uniformity of line width, without negatively affecting other parameters such as the line width, profile angle, and etch selectivities of ARC:photoresist and of oxide:photoresist. At relatively higher pressures, the within wafer uniformity of line width, LER, and LWR may be reduced independently of the plasma precursor gas mixture.

At step 308, a gas mixture including CF₄ and CHF₃ at a ratio between about 2.5:1 and about 5.0:1 is flowed into the etch apparatus (e.g., using gas sources 204, 206 of FIG. 2). The line width can be independently decreased by about 20 nm by tuning the CF₄/CHF₃ ratio towards “leaner” process conditions such as 5:1, while maintaining LER, profile angle, and within wafer uniformity. Line edge microloading between dense (line/space=1/0.7) and isolated (line/space=1:1.7) features is controlled by the CF₄/CHF₃ ratio and chamber pressure. Optionally, argon may also be used.

At step 310, RF power is applied to the electrode between about 300 W and about 500 W (e.g., using RF power source 224) to form a plasma from the gas mixture.

At step 312, the formed plasma anisotropically etches the dielectric layer through the patterned photoresist with reduced LER and LWR. There are three types of dry etch processes: those that have a physical basis (e.g., ion beam milling), those that have a chemical basis (e.g., non-plasma assisted chemical etching), and those that combine both physical and chemical mechanisms (e.g., reactive ion etching and some types of plasma-assisted etching). Primarily physical dry etch methods may not exhibit sufficient selectivity of the superjacent layer over the underlying layer causing punchthrough of the underlying layer. On the other hand, primarily chemical processes typically etch isotropically and therefore do not form vertical sidewalls. Consequently, chemically enhanced ion etching processes that combine the two mechanisms are preferred. Accordingly, in one embodiment, the method of the present invention utilizes a dry etch involving simultaneous ion bombardment and polymerizing chemistry to etch dielectric layer 108 with reduced LER and LWR.

It has been determined that high RF power (e.g., about 500 W), decreased polymerizing CF₄/CHF₃ ratios (e.g., about 2.5:1), low pressure (e.g., 75 mT), and high Ar flow (e.g., about 150 sccm) have a detrimental effect on LER, LWR, and within wafer uniformities. Increasing the Ar flow to enable running the process at higher pressures (e.g., about 200 mT) has been determined to disadvantageously increase LER and LWR. Conversely, it has been determined that lower RF power, higher polymerizing CF₄/CHF₃ ratios, higher pressure, and lower Ar flow have a beneficial effect on LER, LWR, and within wafer uniformities. The effects of the above described parameter trends can be magnified or reduced to form lines with desired LER and LWR control.

In one example, the present invention provides for an etched dielectric layer that has a line edge roughness of about 4 nm and a line width roughness of about 6.7 with the chamber pressure at about 150 mT, a CF₄/CHF₃ ratio at about 5.0:1, RF power at about 300 W, and argon flow at about 50 sccm. In yet another example, the etching of the dielectric layer provides for line width and space features of about 0.22 μm and about 0.16 μm, respectively.

In one embodiment, the etch step 312 may be terminated by an endpoint detection system which optically detects a pre-selected endpoint (e.g., spectral analysis detecting the presence of certain chemistry, a shift in reflectance).

By way of a further example, it is understood that the configuring of an etchback tool to provide a desired LER and/or LWR in response to pre-selected parameters, such as for gas mixture, chamber pressure, and bias power, may be automated. An etchback tool or process in accordance with the present disclosure may therefore include the use of a computer to carry out the automatic settings of parameters to realize a computer-determined or otherwise specified LER and/or LWR. A computer-readable medium or another form of a software product or machine-instructing means (including but not limited to, a hard disk, a compact disk, a flash memory stick, a downloading of manufactured instructing signals over a network and/or like software products) may be used for instructing an instructable machine (e.g., a plasma etch tool) to carry out such automated activities. As such, it is within the scope of the disclosure to have an instructable machine carry out, and/or to provide a software product adapted for causing an instructable plasma etch machine to carry out the disclosed etch process.

Advantageously, the present invention provides for plasma etch methods to reduce and control LER and LWR while maintaining the target line width, thereby maintaining a small variation from the line width nominal value in an efficient manner. The present disclosure also provides for tight wafer center-to-edge line width, LER and LWR uniformity.

The present disclosure is to be taken as illustrative rather than as limiting the scope, nature, or spirit of the subject matter claimed below. Numerous modifications and variations will become apparent to those skilled in the art after studying the disclosure, including use of equivalent functional and/or structural substitutes for elements described herein, use of equivalent functional couplings for couplings described herein, and/or use of equivalent functional steps for steps described herein. Such insubstantial variations are to be considered within the scope of what is contemplated here. Moreover, if plural examples are given for specific means, or steps, and extrapolation between and/or beyond such given examples is obvious in view of the present disclosure, then the disclosure is to be deemed as effectively disclosing and thus covering at least such extrapolations. Given the above disclosure of general concepts and specific embodiments, the scope of protection sought is to be defined by the claims appended hereto.

What is claimed is:

1. A method comprising:
providing a plasma etch reactor including a vacuum chamber and an electrode disposed inside of the chamber;
providing a stack to be etched over the electrode, the stack including a patterned photoresist over a dielectric layer;
providing a chamber pressure between about 75 mT and about 150 mT;
flowing gases including CF₄ and CHF₃ at a ratio between about 2.5:1 and about 5.0:1 into the chamber;
applying RF power to the electrode between about 300 W and about 500 W to form a plasma from the gases; and
etching the dielectric layer with the plasma through the patterned photoresist.

2. The method of claim 1, wherein the etched dielectric layer has a line edge roughness of about 4 nm with the chamber pressure at about 150 mT, a CF₄/CHF₃ ratio at about 5.0:1, and RF power at about 300 W.

3. The method of claim 1, wherein the etched dielectric layer has a line width roughness of about 6.7 nm with the chamber pressure at about 150 mT, a CF₄/CHF₃ ratio at about 5.0:1, and RF power at about 300 W.

4. The method of claim 1, wherein the dielectric layer includes an oxide or a nitride.

5. The method of claim 1, wherein the dielectric layer includes a plasma enhanced SiH₄ oxide.

6. The method of claim 5, further comprising etching a polysilicon layer using the etched plasma enhanced SiH₄ oxide as a hardmask.

7. The method of claim 1, wherein the photoresist is sensitive at 193 nm.

8. The method of claim 1, wherein the etching of the dielectric layer provides for line width and space features of about 0.22 μm and about 0.16 μm, respectively.

9. The method of claim 1, further comprising flowing argon (Ar) at about 50 sccm into the chamber.

10. The method of claim 1, further comprising etching the dielectric layer through an organic anti-reflective coating (ARC) layer and a SiON layer formed between the photoresist and the dielectric layer.

11. A method comprising:
providing a substrate;
providing a polysilicon layer over the substrate;
providing an oxide layer over the polysilicon layer;
providing a SiON layer over the oxide layer;
providing an ARC layer over the SiON layer;
providing a patterned photoresist over the ARC layer;
etching the oxide layer through the photoresist, the ARC layer, and the SiON layer with a plasma formed with a gas mixture including CH₄ and CHF₃ at a ratio between about 2.5:1 and about 5.0:1, at a pressure between about 75 mT to about 150 mT, and at a bias power level between about 300 W and about 500 W; and
etching the polysilicon layer through the etched oxide layer to form a gate.

12. The method of claim 11, wherein the etched oxide layer has a line edge roughness of about 4 nm with the chamber pressure at about 150 mT, a CF₄/CHF₃ ratio at about 5.0:1, and RF power at about 300 W.

13. The method of claim 11, wherein the etched oxide layer has a line width roughness of about 6.7 nm with the chamber pressure at about 150 mT, a CF₄/CHF₃ ratio at about 5.0:1, and RF power at about 300 W.

14. The method of claim 11, wherein the oxide layer includes a plasma enhanced SiH₄ oxide.

15. The method of claim 11, wherein the photoresist is sensitive at 193 nm.

16. The method of claim 11, wherein the etching of the oxide layer provides for line width and space features of about 0.22 μm and about 0.16 μm, respectively.

17. The method of claim 11, wherein the gas mixture further includes argon (Ar).
